(19) United States
(12) Patent Application Publication
(10) Pub. No.: US 2026/0038540 A1
(43) Pub. Date: Feb. 5, 2026

(54) MEMORY DEVICE AND METHOD OF MANUFACTURING THE MEMORY DEVICE

(71) Applicant: SK hynix Inc., Icheon-si Gyeonggi-do (KR)

(72) Inventors: Na Yeong YANG, Icheon-si Gyeonggi-do (KR); Rho Gyu KWAK, Icheon-si Gyeonggi-do (KR); Mi Seong PARK, Icheon-si Gyeonggi-do (KR); Jung Shik JANG, Icheon-si Gyeonggi-do (KR); Seok Min CHOI, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 19/042,772

(22) Filed: Jan. 31, 2025

(30) Foreign Application Priority Data
Aug. 1, 2024 (KR) 10-2024-0102480

(51) Int. Cl. G11C 5/06; H10B 41/10; H10B 41/27; H10B 43/10; H10B 43/27

(52) U.S. Cl. CPC G11C 5/063; H10B 41/10; H10B 41/27; H10B 43/10; H10B 43/27

(57) ABSTRACT

Provided herein is a memory device and a method of manufacturing the memory device. The memory device includes a stacked structure including a plurality of conductive layers and a plurality of interlayer insulating layers that are alternately stacked in a cell array area and a contact area, a plurality of cell plugs formed within the stacked structure in the cell array area, a plurality of select line contacts coupled to the conductive layer that is allocated as a select line among the plurality of conductive layers, and a separation pattern penetrating the conductive layer that is allocated as the drain select line in the cell array area, the separation pattern extending from the cell array area to the contact area. The separation pattern separates the plurality of select line contacts from each other.

### CROSS-REFERENCE TO RELATED APPLICATION

The present application claims priority under 35 U.S.C. § 119 (a) to Korean patent application number 10-2024-0102480 filed on Aug. 1, 2024, in the Korean Intellectual Property Office, the entire contents of which application is incorporated herein by reference.

### BACKGROUND

### 1. Technical Field

Various embodiments of the present disclosure generally relate to a memory device and a method of manufacturing the memory device, and more particularly to a memory device including a separation pattern and a method of manufacturing the memory device.

### 2. Related Art

A memory device may include a nonvolatile memory device in which stored data is retained even when power is cut off. The nonvolatile memory device may be classified into a two-dimensional (2D) structure and a 3 two-dimensional (3D) structure depending on a structure in which memory cells are arranged. The memory cells of the nonvolatile memory device having the 2D structure may be arranged on a substrate in a single layer. The memory cells of the nonvolatile memory device having the 3D structure may be stacked on a substrate in a vertical direction. Because the integration degree of the nonvolatile memory device having the 3D structure is higher than that of the nonvolatile memory device having the 2D structure, electronic devices using the nonvolatile memory device with the 3D structure are increasing recently.

### SUMMARY

An embodiment of the present disclosure may provide for a memory device. The memory device may include a stacked structure including a plurality of conductive layers and a plurality of interlayer insulating layers that are alternately stacked in a cell array area and a contact area. A plurality of cell plugs may be formed in the stacked structure on the cell array area. A plurality of select line contacts coupled to the conductive layer that is allocated as a select line among the plurality of conductive layers. A separation pattern penetrating the conductive layer that is allocated as the drain select line in the cell array area, the separation pattern extending from the cell array area to the contact area. The separation pattern may separate the plurality of select line contacts from each other.

An embodiment of the present disclosure may provide for a memory device. The memory device may include a stacked structure including a plurality of conductive layers and a plurality of interlayer insulating layers that are alternately stacked in a cell array area and a contact area, the cell array area including first, second, third, and fourth cell areas. A plurality of cell plugs formed within the stacked structure in the cell array area. A plurality of select line contacts coupled to the conductive layer that is allocated as a select line among the plurality of conductive layers. A first separation pattern disposed between the first cell area and the second cell area, and penetrating the conductive layer that is allocated as the drain select line in the cell array area, the first separation pattern extending from the cell array area to the contact area. A second separation pattern disposed between the second cell area and the third cell area, and penetrating the conductive layer that is allocated as the drain select line in the cell array area, the second separation pattern extending from the cell array area to the contact area. A third separation pattern disposed between the third cell area and the fourth cell area, and penetrating the conductive layer that is allocated as the drain select line in the cell array area, the third separation pattern extending from the cell array area to the contact area. The first separation pattern and the third separation pattern may separate the plurality of select line contacts from each other.

An embodiment of the present disclosure may provide for a method of manufacturing a memory device. The method may include forming a stacked structure by alternately stacking a plurality of conductive layers and a plurality of interlayer insulating layers on a cell array area and a contact area, forming a plurality of cell plugs in the stacked structure on the cell array area, forming a pre-select line contact coupled to the conductive layer that is allocated as a select line among the plurality of conductive layers, forming a trench that penetrates the conductive layer that is allocated as the drain select line, the trench extending from the cell array area to the contact area, and filling the trench with an insulating layer to form a separation pattern. The trench may penetrate the pre-select line contact to separate the pre-select line contact into a plurality of select line contacts.

An embodiment of the present disclosure may provide for a method of manufacturing a memory device. The method may include forming a stacked structure by alternately stacking a plurality of conductive layers and a plurality of interlayer insulating layers in a cell array area and a contact area, the cell array area including a first cell area and a second cell area, forming a plurality of cell plugs within the stacked structure in the cell array area, forming a first select line contact and a second select line contact coupled to the conductive layer that is allocated as a select line, forming a trench that penetrates the conductive layer that is allocated as the drain select line between the first cell area and the second cell area, the trench extending from the cell array area to the contact area, and filling the trench with an insulating layer to form a separation pattern. The trench may separate the first select line contact and the second select line contact from each other.

### BRIEF DESCRIPTION OF THE DRAWINGS

FIG. 1 is a diagram illustrating a memory device according to an embodiment of the present disclosure.

FIG. 2 is a diagram illustrating the structure of a memory cell array according to an embodiment of the present disclosure.

FIGS. 3A, 3B, and 3C are views for explaining the structure of a memory device according to an embodiment of the present disclosure.

FIGS. 4A, 4B, 5A, 5B, 5C, 6, 7A, 7B, 7C, 8A, 8B, 8C, 9A, and 9B are views for explaining a method of manufacturing a memory device according to an embodiment of the present disclosure.

FIGS. 10A, 10B, 11A, and 11B are views for explaining a method of manufacturing a memory device according to an embodiment of the present disclosure.

FIG. 12 is a block diagram illustrating the configuration of a memory system according to an embodiment of the present disclosure.

FIG. 13 is a block diagram illustrating the configuration of a memory system according to an embodiment of the present disclosure.

FIG. 14 is a block diagram illustrating the configuration of a computing system according to an embodiment of the present disclosure.

FIG. 15 is a block diagram illustrating a computing system according to an embodiment of the present disclosure.

### DETAILED DESCRIPTION

Specific structural or functional descriptions in the embodiments of the present disclosure introduced in this specification or application are provided as examples to describe embodiments according to the concept of the present disclosure. The embodiments according to the concept of the present disclosure may be practiced in various forms, and should not be construed as being limited to the embodiments described in the specification or application.

It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout.

Various embodiments of the present disclosure are directed to a memory device and a method of manufacturing the memory device, which can reduce the difficulty of a process and reduce defects in the process.

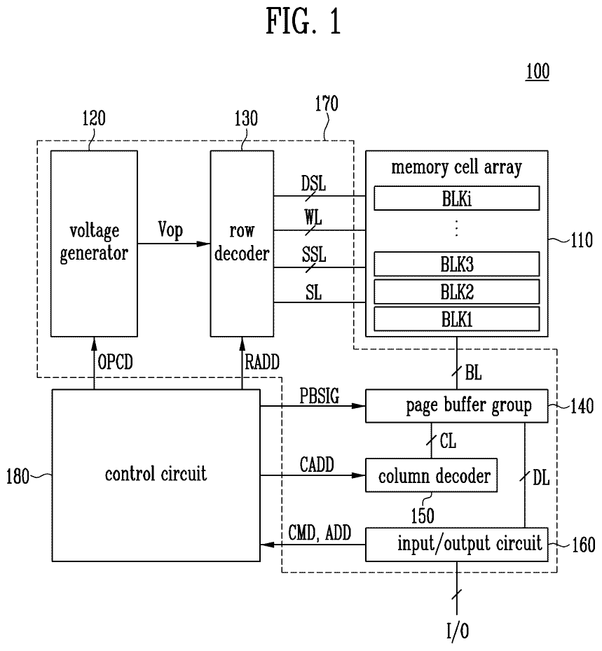

FIG. 1 is a diagram illustrating a memory device according to an embodiment of the present disclosure.

Referring to FIG. 1, a memory device 100 may include a memory cell array 110, a peripheral circuit 170, and a control circuit 180.

The memory cell array 110 may include first to i-th memory blocks BLK1 to BLKi. Each of the first to i-th memory blocks BLK1 to BLKi may include a plurality of memory cells that are capable of storing data. Drain select lines DSL, word lines WL, source select lines SSL, and a source line SL may be connected to each of the first to i-th memory blocks BLK1 to BLKi, and bit lines BL may be connected in common to the first to i-th memory blocks BLK1 to BLKi.

Each of the first to i-th memory blocks BLK1 to BLKi may be formed to have a three-dimensional (3D) structure. Each memory block having a 3D structure may include memory cells stacked in a direction vertical to a substrate.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 170 may perform a program operation of storing data in the memory cell array 110, a read operation of outputting data stored in the memory cell array 110, and an erase operation of erasing data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop required for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a selected memory block through the row decoder 130.

The program voltages may be voltages that are applied to a selected word line among the word lines WL during a program operation, and may be used to increase the threshold voltages of memory cells connected to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off drain select transistors or source select transistors. For example, the turn-off voltage may be set to 0 V. The precharge voltages are voltages higher than 0 V, and may be applied to the bit lines during a read operation. The verify voltages may be used for a verify operation of determining whether the threshold voltages of the selected memory cells have increased up to target levels. The verify voltages may be set to various levels depending on the target levels, and may be applied to the selected word line.

The read voltages may be applied to the selected word line during a read operation on the selected memory cells. For example, the read voltages may be set to various levels according to the program scheme of the selected memory cells. The pass voltages may be voltages that are applied to unselected word lines, among the word lines WL, during a program or read operation, and may be used to turn on memory cells connected to the unselected word lines. The erase voltages may be used for an erase operation of erasing the memory cells included in the selected memory block, and may be applied to the source line SL.

The row decoder 130 may transfer the operating voltages Vop to the drain select lines DSL, the word lines WL, the source select lines SSL, and the source line SL, which are connected to a memory block selected in response to a row address RADD. For example, the row decoder 130 may be connected to the voltage generator 120 through global lines, and may be connected to the first to i-th memory blocks BLK1 to BLKi through the drain select lines DSL, the word lines WL, the source select lines SSL, and the source line SL.

The page buffer group 140 may include page buffers (not illustrated) connected to the first to i-th memory blocks BLK1 to BLKi, respectively. For example, respective page buffers (not illustrated) may be connected to the first to i-th memory blocks BLK1 to BLKi through bit lines BL. During a read operation, the page buffers (not illustrated) may sense currents or voltages of the bit lines that vary depending on the threshold voltages of selected memory cells in response to page buffer control signals PBSIG, and may store sensed data.

The column decoder 150 may be configured such that data is transferred between the page buffer group 140 and the input/output circuit 160 in response to a column address CADD. For example, the column decoder 150 may be connected to the page buffer group 140 through column lines CL, and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 180, and may transmit the data, received from the external controller through the input/output lines I/O, to the page buffer group 140. Alternatively, the input/output circuit 160 may output data, received from the page buffer group 140, to the external controller through the input/output lines I/O.

The control circuit 180 may output at least one of the operation code OPCD, the row address RADD, the page buffer control signals PBSIG, or the column address CADD in response to the command CMD and the address ADD. For example, when the command CMD input to the control circuit 180 is a command corresponding to a program operation, the control circuit 180 may control the peripheral circuit 170 so that a program operation is performed on a memory block selected by the address ADD. When the command CMD input to the control circuit 180 is a command corresponding to a read operation, the control circuit 180 may control the peripheral circuit 170 so that a read operation is performed on a memory block selected by the address and read data is output. When the command CMD input to the control circuit 180 is a command corresponding to an erase operation, the control circuit 180 may control the peripheral circuit 170 so that an erase operation is performed on a selected memory block.

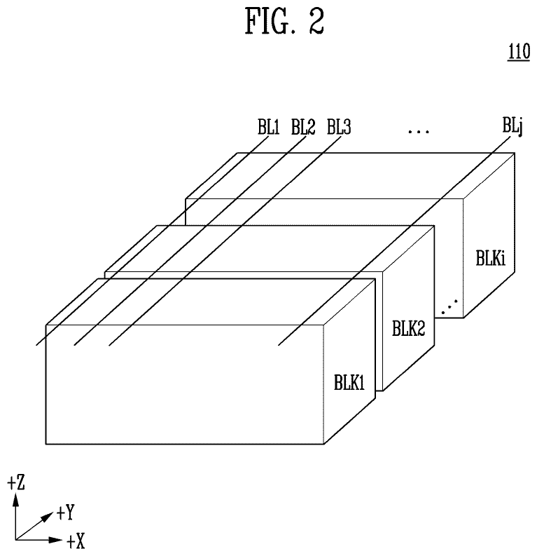

FIG. 2 is a diagram illustrating the structure of a memory cell array according to an embodiment of the present disclosure.

Referring to FIG. 2, the memory cell array 110 may include the first to i-th memory blocks BLK1 to BLKi. The first to i-th memory blocks BLK1 to BLKi may be arranged to be spaced apart from each other along a Y axis. The first to i-th memory blocks BLK1 to BLKi may extend along an X axis.

The first to i-th memory blocks BLK1 to BLKi may be connected in common to first to j-th bit lines BL1 to BLj. For example, the first to j-th bit lines BL1 to BLj may extend along the Y axis, and may be arranged to be spaced apart from each other along the X axis. The first to j-th bit lines BL1 to BLj may be connected, respectively, to the first to i-th memory blocks BLK1 to BLKi on the first to i-th memory blocks BLK1 to BLKi.

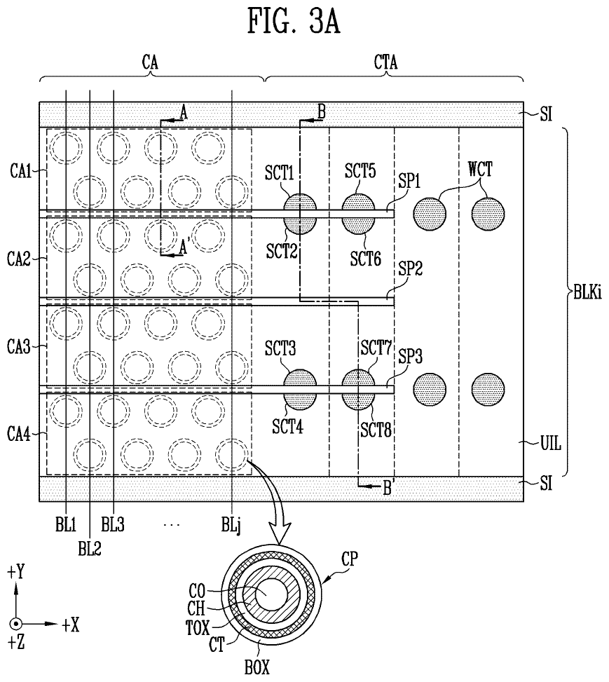

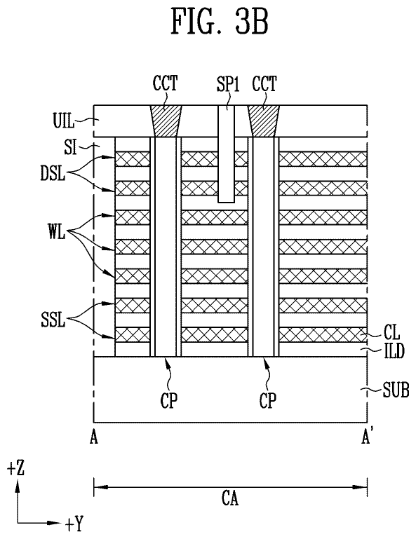

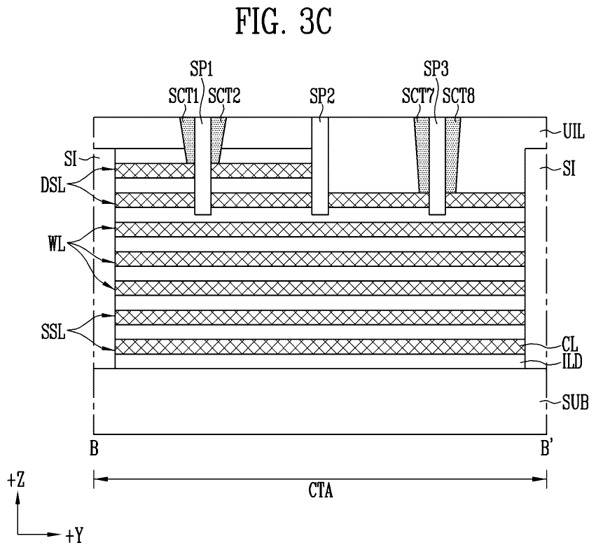

FIGS. 3A, 3B, and 3C are views for explaining the structure of a memory device according to an embodiment of the present disclosure.

FIG. 3A may be a layout view of an i-th memory block BLKi. FIG. 3B may be a sectional view taken along line A-A′ of FIG. 3A. FIG. 3C may be a sectional view taken along line B-B′ of FIG. 3A.

Referring to FIGS. 3A, 3B, and 3C, the i-th memory block BLKi may be distinguished from neighboring memory blocks by a slit SI. For instance, the slit SI may be positioned in each of the +Y direction and the −Y direction of the i-th memory block BLKi, and may extend along the X-axis. The i-th memory block BLKi may be adjacent to other memory blocks with the slit SI interposed therebetween.

The i-th memory block BLKi may include a cell array area CA and a contact area CTA. For instance, the contact area CTA may be positioned in the +X direction of the cell array area CA. Although it is shown in FIG. 3A that the contact area CTA is positioned on only one side of the cell array area CA, contact areas CTA may be positioned on both sides of the cell array area CA. For instance, a first contact area may be positioned in the −X direction of the cell array area CA, and a second contact area may be positioned in the +X direction of the cell array area CA.

The cell array area CA may include a plurality of cell plugs CP. The cell plugs CP may be formed in a vertical direction (e.g., +Z direction) from a substrate SUB. The cell plugs CP may be arranged in a plurality of rows. Each row may include the cell plugs CP spaced apart from each other along the X-axis. The plurality of rows may be spaced apart from each other along the Y-axis. Centers of the cell plugs CP included in odd-numbered rows may be offset from centers of the cell plugs CP included in even-numbered rows. For instance, the cell plugs CP that are adjacent to each other in the +Y direction may be arranged in a zigzag fashion. Although FIG. 3A illustrates an embodiment in which the plurality of cell plugs CP are arranged in eight rows in the cell array area CA, the present disclosure is not limited thereto. For instance, the i-th memory block BLKi may include cell plugs CP composed of eight rows or fewer or eight rows or more in the cell array area CA.

The cell plugs CP each may include a cylindrical blocking layer BOX, a charge trap layer CT formed along an inner wall of the blocking layer BOX, a tunnel isolation layer TOX formed along an inner wall of the charge trap layer CT, a channel layer CH formed along an inner wall of the tunnel isolation layer TOX, and a core pillar CO formed in a cylindrical shape in an area enclosed by the channel layer CH. The blocking layer BOX and the tunnel isolation layer TOX each may be formed of an oxide layer (e.g., silicon oxide layer). The charge trap layer CT may be formed of a nitride layer. The channel layer CH may be formed of a doped silicon layer. The core pillar CO may be formed of an insulating layer or a conductive layer. The blocking layer BOX, the charge trap layer CT, the tunnel isolation layer TOX, the channel layer CH, and the core pillar CO formed in the cell plug CP may extend in the vertical direction Z.

Bit lines may be positioned on the cell array area CA of the i-th memory block BLKi. For instance, first to j-th bit lines BL1 to BLj may be positioned on the cell array area CA. The first to j-th bit lines BL1 to BLj may be arranged to be spaced apart from each other along the X-axis. Furthermore, each of the first to j-th bit lines BL1 to BLj may extend along the Y-axis. Each of the first to j-th bit lines BL1 to BLj may be coupled to at least one cell plug CP.

The contact area CTA may include a stepped structure. Contacts may be formed in the contact area CTA. For instance, a plurality of select line contacts SCT1 to SCT8 and a plurality of word line contacts WCT may be formed in the contact area CTA. Each of the word line contacts WCT may be coupled to each of the word lines WL of FIG. 1. Further, each of the select line contacts SCT1 to SCT8 may be coupled to each of the drain select lines DSL of FIG. 1.

The i-th memory block BLKi may include at least one separation pattern. In an embodiment of the present disclosure, a structure including first to third separation patterns SP1, SP2, and SP3 will be described as an example. The first to third separation patterns SP1, SP2, and SP3 may be spaced apart from each other in the Y-axis direction. Each of the first to third separation patterns SP1, SP2, and SP3 may extend along the X-axis. For example, each of the first to third separation patterns SP1, SP2, and SP3 may extend in the −X direction (or the +X direction). The cross-section of each of the first to third separation patterns SP1, SP2, and SP3 may have a major axis in the +X direction and a minor axis in the +Y direction. The first to third separation patterns SP1, SP2, and SP3 may be arranged to be parallel to each other.

The cell array area CA may be divided into a plurality of cell areas by the first to third separation patterns SP1, SP2, and SP3. For instance, the first separation pattern SP1 may be positioned between the first cell area CA1 and the second cell area CA2. The second cell area CA2 may be positioned in the −Y direction of the first cell area CA1. The second separation pattern SP2 may be positioned between the second cell area CA2 and the third cell area CA3. The third cell area CA3 may be positioned in the −Y direction of the second cell area CA2. The third separation pattern SP3 may be positioned between the third cell area CA3 and the fourth cell area CA4. The fourth cell area CA4 may be positioned in the −Y direction of the third cell area CA3. As illustrated in FIG. 3A, when three separation patterns SP1, SP2, and SP3 are included in the i-th memory block BLKi, the cell array area CA may be divided into four cell areas (e.g., CA1, CA2, CA3, and CA4). When the i-th memory block BLKi includes N separation patterns, the cell array area CA may be divided into N+1 cell areas.

The i-th memory block BLKi may include conductive layers CL stacked along the Z-axis, and interlayer insulating layers ILD formed between the conductive layers CL. An upper insulating layer UIL may be formed on a stacked structure including the conductive layers CL and the interlayer insulating layers ILD. The conductive layers CL may include at least one drain select line DSL, a plurality of word lines WL, and at least one source select line SSL. It can be understood that only a portion of the stacked conductive layers CL is depicted in FIGS. 3B and 3C. In an embodiment of the present disclosure, a structure in which two drain select lines DSL are stacked will be described as an example.

The cell plugs CP penetrating the conductive layers CL and the interlayer insulating layers ILD in the Z-axis direction may be formed in the cell array area CA. Cell contacts CCT may be formed on the cell plugs CP. The cell plugs CP may be coupled to the bit lines BL1 to BLj through the cell contacts CCT.

The first separation pattern SP1 may be formed between the first cell area CA1 and the second cell area CA2. The first separation pattern SP1 may be formed to a depth that separates the drain select lines DSL. For instance, the drain select lines DSL corresponding to the first cell area CA1 and the drain select lines DSL corresponding to the second cell area CA2 may be separated from each other by the first separation pattern SP1. Further, the first separation pattern SP1 may extend to the contact area CTA, and may separate the first select line contact SCT1 and the second select line contact SCT2 formed on the contact area CTA from each other. The first select line contact SCT1 and the second select line contact SCT2 may be positioned adjacent to each other, and each of the first select line contact SCT1 and the second select line contact SCT2 may be coupled to the drain select line DSL located at the uppermost position among the stacked conductive layers CL. In some embodiments, the drain select line DSL located at the uppermost position is the conductive layer CL directly coupled to a select line contact without any intervening conductive layer or layers between the drain select line DSL located at the uppermost position and the select line contact. For example, as shown in FIG. 3C the drain select line DSL located at the uppermost position is the conductive layer CL directly coupled to the first select line contact SCT1 and the second select line contact SCT2 and for reference is the conductive layer CL positioned furthest away from the substrate SUB in this example. For example, as shown in FIG. 3C the drain select line DSL located at the uppermost position is the conductive layer CL directly coupled to the seventh select line contact SCT7 and the eighth select line contact SCT8 and for reference is the conductive layer CL positioned second furthest away from the substrate SUB in this example. The first select line contact SCT1 and the second select line contact SCT2 may extend to the same depth.

Furthermore, the first separation pattern SP1 may separate a fifth select line contact SCT5 and a sixth select line contact SCT6 formed on the contact area CTA from each other. The fifth select line contact SCT5 and the sixth select line contact SCT6 may be positioned adjacent to each other, and each of the fifth select line contact SCT5 and the sixth select line contact SCT6 may be coupled to the drain select line DSL positioned under the drain select line DSL disposed on the uppermost portion among the stacked conductive layers CL to be adjacent thereto. The fifth select line contact SCT5 and the sixth select line contact SCT6 may extend to the same depth.

As described above, the first separation pattern SP1 may separate the drain select lines DSL corresponding to the first cell area CA1 and the drain select lines DSL corresponding to the second cell area CA2 from each other, and may separate the first select line contact SCT1 and the fifth select line contact SCT5 coupled to the drain select lines DSL corresponding to the first cell area CA1, and the second select line contact SCT2 and the sixth select line contact SCT6 coupled to the drain select lines DSL corresponding to the second cell area CA2.

The second separation pattern SP2 may be formed between the second cell area CA2 and the third cell area CA3. The second separation pattern SP2 may be formed to a depth that separates the drain select lines DSL. For instance, the drain select lines DSL corresponding to the second cell area CA2 and the drain select lines DSL corresponding to the third cell area CA3 may be separated from each other by the second separation pattern SP2. Further, the second separation pattern SP2 may extend to the contact area CTA.

The third separation pattern SP3 may be formed between the third cell area CA3 and the fourth cell area CA4. The third separation pattern SP3 may be formed to a depth that separates the drain select lines DSL. For instance, the drain select lines DSL corresponding to the third cell area CA3 and the drain select lines DSL corresponding to the fourth cell area CA4 may be separated from each other by the third separation pattern SP3. Further, the third separation pattern SP3 may extend to the contact area CTA, and may separate the third select line contact SCT3 and the fourth select line contact SCT4 formed on the contact area CTA from each other. The third select line contact SCT3 and the fourth select line contact SCT4 may be positioned adjacent to each other, and each of the third select line contact SCT3 and the fourth select line contact SCT4 may be coupled to the drain select line DSL disposed on the uppermost portion among the stacked conductive layers CL. The third select line contact SCT3 and the fourth select line contact SCT4 may extend to the same depth.

Furthermore, the third separation pattern SP3 may separate a seventh select line contact SCT7 and an eighth select line contact SCT8 formed on the contact area CTA from each other. The seventh select line contact SCT7 and the eighth select line contact SCT8 may be positioned adjacent to each other, and each of the seventh select line contact SCT7 and the eighth select line contact SCT8 may be coupled to the drain select line DSL positioned under the drain select line DSL disposed on the uppermost portion among the stacked conductive layers CL to be adjacent thereto. The seventh select line contact SCT7 and the eighth select line contact SCT8 may extend to the same depth.

As described above, the third separation pattern SP3 may separate the drain select lines DSL corresponding to the third cell area CA3 and the drain select lines DSL corresponding to the fourth cell area CA4 from each other, and may separate the third select line contact SCT3 and the seventh select line contact SCT7 coupled to the drain select lines DSL corresponding to the third cell area CA3, and the fourth select line contact SCT4 and the eighth select line contact SCT8 coupled to the drain select lines DSL corresponding to the fourth cell area CA4.

The contact area CTA may include a stepped structure formed on a side of the cell array area CA. For instance, the contact area CTA may include a stepped structure extending from the cell array area CA in the +X direction. For instance, the contact area CTA may include pads through which the drain select lines DSL, the word lines WL, and the source select lines SSL are exposed.

The select line contacts SCT1 to SCT8 may be formed in the contact area CTA. The select line contacts SCT1, SCT2, SCT3, and SCT4 may be coupled to the drain select line DSL positioned on the uppermost portion among the plurality of conductive layers CL, and the select line contacts SCT5, SCT6, SCT7, and SCT8 may be coupled to the drain select line DSL positioned under the drain select line DSL positioned on the uppermost portion to be adjacent thereto. The word line contacts WCT may be coupled to the word lines WL, respectively. The drain select lines DSL may receive an operating voltage Vop through the select line contacts SCT1 to SCT8. Further, the word lines WL may receive an operating voltage Vop through the word line contacts WCT.

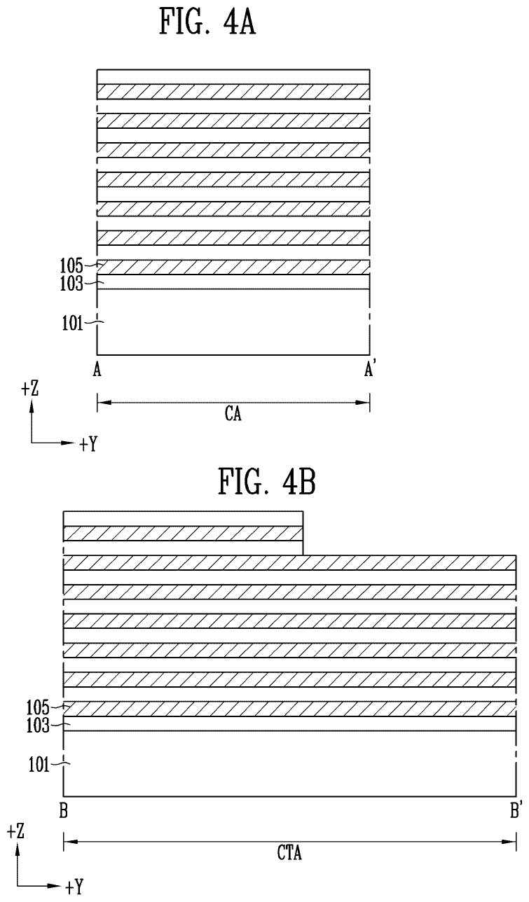

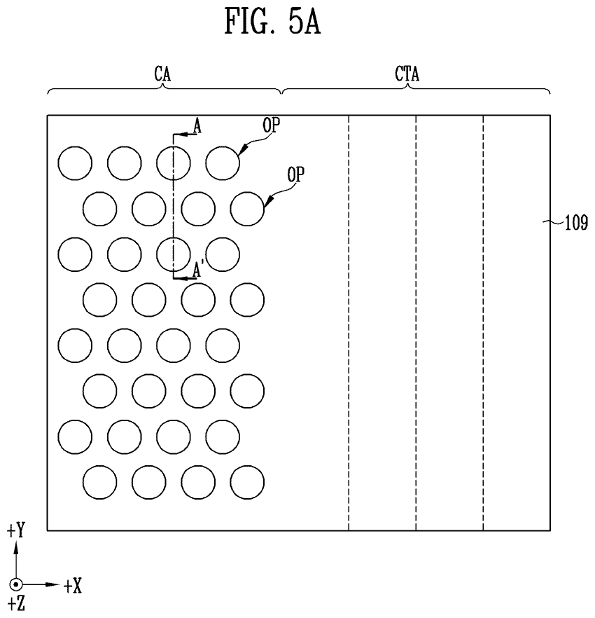

FIGS. 4A, 4B, 5A, 5B, 5C, 6, 7A, 7B, 7C, 8A, 8B, 8C, 9A, and 9B are views for explaining a method of manufacturing a memory device according to an embodiment of the present disclosure.

Referring to FIGS. 4A and 4B, a source line layer 101 is formed on the cell array area CA and the contact area CTA of the memory device. The source line layer 101 may be a doped semiconductor layer, for example, a semiconductor layer doped with an n-type impurity. In an embodiment, the source line layer 101 may be formed by implanting the impurity into a surface of the substrate SUB illustrated in FIGS. 3B and 3C, or by depositing at least one doped silicon layer on the substrate SUB.

Subsequently, a stacked structure 103 and 105 are formed by alternately stacking first material layers 103 and second material layers 105 in the cell array area CA and the contact area CTA. The second material layers 105 may be layers for forming conductive layers such as a word line, a select line, or a pad, while the first material layers 103 may be interlayer insulating layers for insulating the stacked conductive layers from each other.

The first material layers 103 are formed of a material having a high etch selectivity with respect to the second material layers 105. For example, the first material layers 103 may include an insulating material such as an oxide, while the second material layers 105 may include a sacrificial material such as a nitride.

Subsequently, a stepped structure may be formed by partially etching the stacked structure 103 and 105 in the contact area CTA. For example, a portion of the first material layers 103 and the second material layers 105 may be etched so that each of the first and second material layers 103 and 105 is exposed.

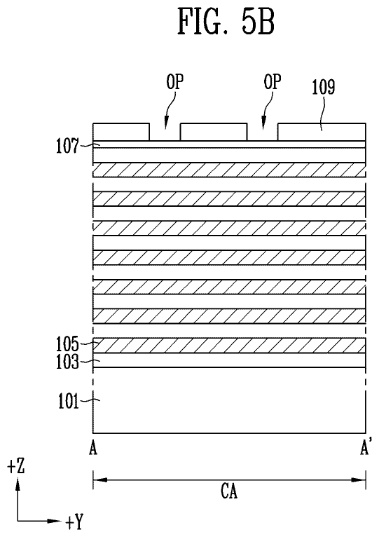

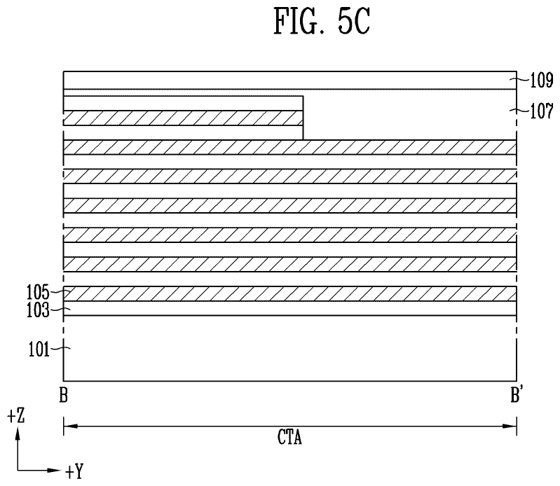

Referring to FIGS. 5A, 5B, and 5C, a first upper insulating layer 107 is formed on an entire structure of the cell array area CA and the contact area CTA. The steps of the stepped structure of the contact area CTA may be eliminated by the first upper insulating layer 107. For instance, the first upper insulating layer 107 may be formed of an oxide layer.

Subsequently, a mask pattern 109 is formed on the first upper insulating layer 107. The mask pattern 109 is formed so that a portion where each of the cell plugs is to be formed in the cell array area CA has an opening OP.

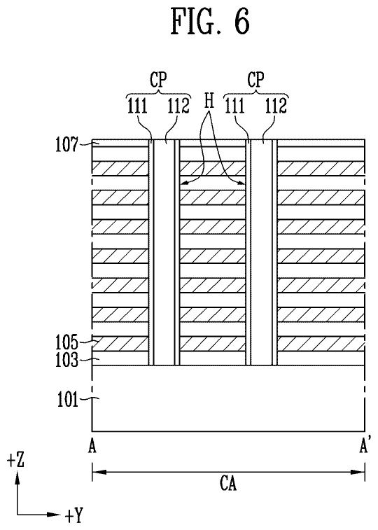

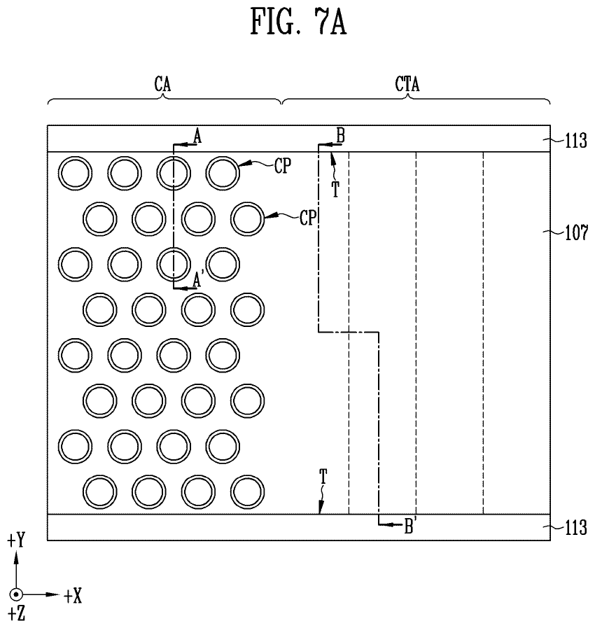

Referring to FIG. 6, holes H passing through the stacked structure 103 and 105 are formed by etching the stacked structure 103 and 105 using the mask pattern 109 (see FIG. 5B) as a barrier. At this time, the contact area CTA (see FIGS. 5A and 5C) is prevented from being etched by the mask pattern, so that no hole is formed.

Thereafter, the mask pattern is removed.

Subsequently, the cell plugs CP each including a channel layer 112 and a memory layer enclosing the channel layer 112 are formed in the holes H. For instance, the memory layer 111 is formed on the sidewall of each hole H. The memory layer 111 may include at least one of a blocking layer, a charge trap layer, and a tunnel isolation layer, and the charge trap layer may include a floating gate such as silicon, a charge trap material such as nitride, a phase change material, a nano dot, etc. Thereafter, each hole H is completely filled with the channel layer 112 up to the central area of the hole to form the cell plug CP. In an embodiment, the channel layer 112 may be formed as a hollow structure with an open central area of each hole H, and a core pillar may be formed in the open central area.

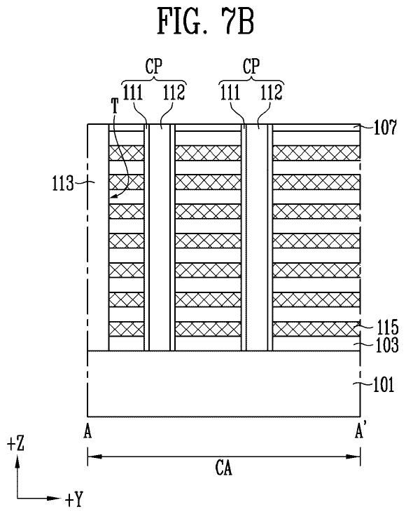

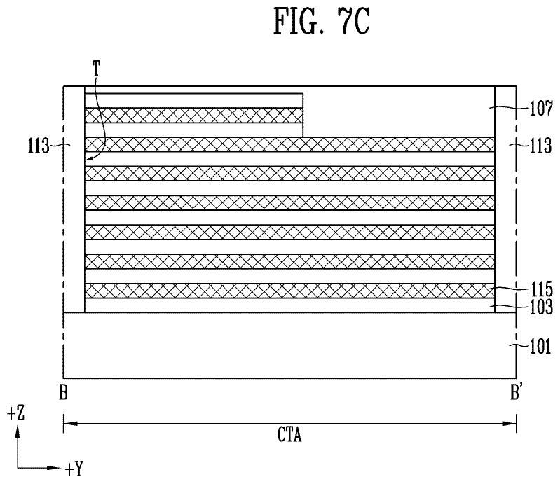

Referring to FIGS. 7A, 7B, and 7C, in the cell array area CA, the stacked structure 103 and 105 is etched at both ends of the Y-axis of an area where the cell plugs CP are arranged, thereby forming trenches T that extend in the X-axis direction. The sidewalls of the first material layers 103 and the second material layers 105 (see FIG. 6) of the stacked structure 103 and 105 may be exposed by the trenches T. The trenches T may extend in a line shape from the cell array area CA to the contact area CTA.

Subsequently, the second material layers exposed through the trenches T are removed, and conductive layers 115 are formed in a space where the second material layers are removed. Among the conductive layers 115, at least one conductive layer 115 positioned at the lowermost portion may be a source select line, at least one conductive layer 115 positioned at the uppermost portion may be a drain select line, and the remaining conductive layers 115 may be word lines. The conductive layers 115 formed on the contact area CTA extend to have different lengths in the X-axis direction, and a conductive layer disposed on a lower portion extends longer in the X-axis direction. Thus, each of the conductive layers 115 formed on the contact area CTA may include an area that does not overlap a conductive layer disposed at an upper position, and the area that does not overlap the conductive layer disposed at the upper position may be defined as a pad.

Subsequently, the trenches T are filled with an insulating layer to form the slit 113. The slit 113 may be formed of an oxide layer.

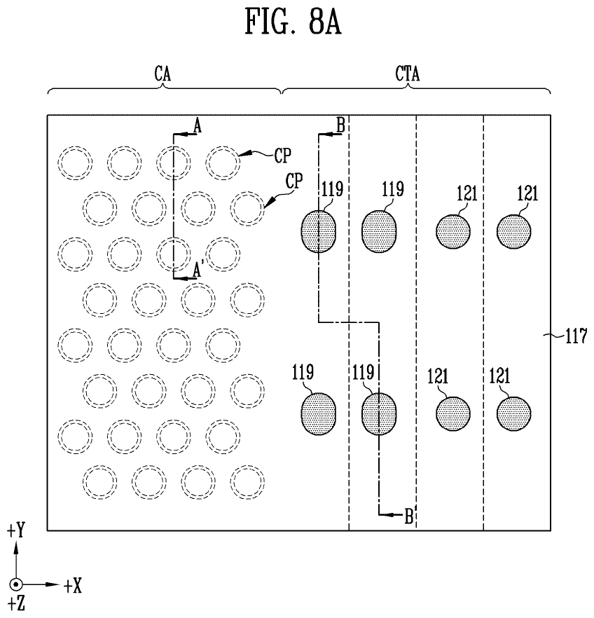

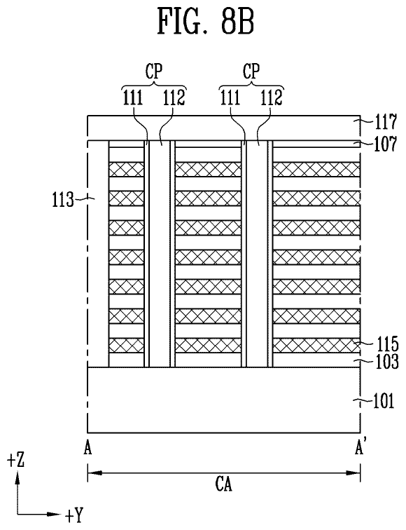

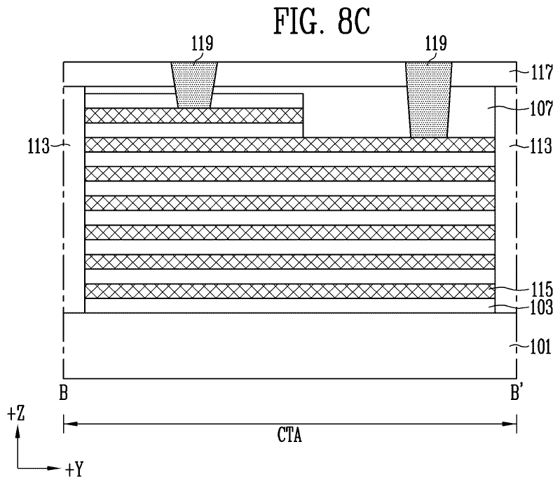

Referring to FIGS. 8A, 8B, and 8C, a second upper insulating layer 117 is formed over the entire structure of the cell array area CA and the contact area CTA. The second upper insulating layer 117 may be formed of an oxide layer.

Subsequently, a portion of the pad of the conductive layers 115 may be exposed through an etching process that etches the second upper insulating layer 117 and the first upper insulating layer 107 formed on the contact area CTA. As the etching process, an anisotropic dry etching process may be performed. Further, pre-select line contacts 119 and word line contacts 121 contacting the pad of the exposed conductive layers 115 may be formed. For instance, the cross-section of each pre-select line contact 119 in a horizontal direction may be circular, elliptical, or rectangular.

In an embodiment, when the cell array area CA is divided into four cell areas CA1, CA2, CA3, and CA4 as illustrated in FIG. 3A, one pre-select line contact 119 may be formed for two adjacent cell areas.

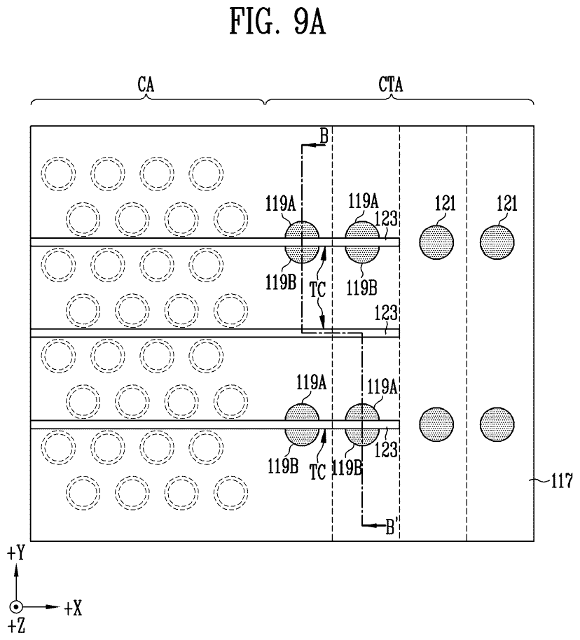

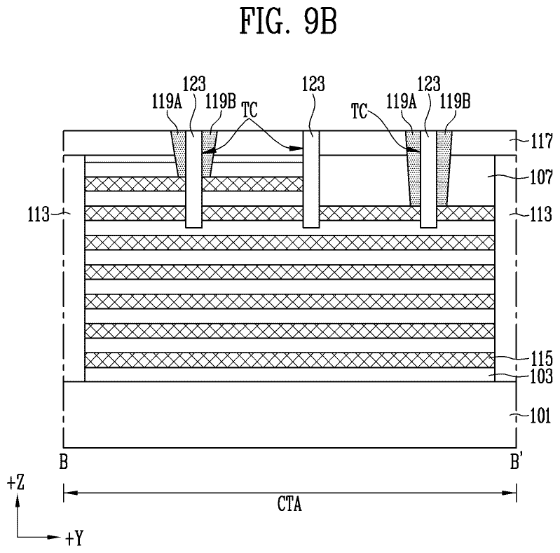

Referring to FIGS. 9A and 9B, the etching process is performed to form trenches TC penetrating the second upper insulating layer 117, the first upper insulating layer 107, at least two first material layers 103 disposed on an upper portion among the plurality of first material layers 103, and at least one conductive layer 115 disposed on an upper portion among the plurality of conductive layers 115. As the etching process for forming the trenches TC, an anisotropic dry etching process may be performed.

The trenches TC may correspond to the first to third separation patterns SP1 to SP3 illustrated in FIGS. 3A, 3B, and 3C, respectively. For instance, any one of the trenches TC may extend in a line shape along the X-axis between the first cell area CA1 (see FIG. 3A) and the second cell area CA2 (see FIG. 3A). Further, any one of the trenches TC may extend in a line shape along the X-axis between the second cell area CA2 (see FIG. 3A) and the third cell area CA3 (see FIG. 3A). Furthermore, any one of the trenches TC may extend in a line shape along the X-axis between the third cell area CA3 (see FIG. 3A) and the fourth cell area CA4 (see FIG. 3A). The trenches TC may be formed to penetrate the upper conductive layers 115 used as the drain select line, among the plurality of conductive layers 115. Thus, the conductive layers 115 disposed on the upper portion and used as the drain select lines corresponding to the first cell area CA1 (see FIG. 3A), the second cell area CA2 (see FIG. 3A), the third cell area CA3 (see FIG. 3A), and the fourth cell area CA4 (see FIG. 3A) are separated from each other by the trenches TC.

In an embodiment, although it is shown that the trenches TC are formed between the cell plugs CP, some trenches TC may be formed to overlap some of the cell plugs CP. In this case, the cell plugs CP overlapping some trenches TC may be referred to as dummy cell plugs.

The trenches TC may extend to the contact area CTA, and some trenches TC may penetrate the pre-select line contacts 119 (see FIG. 8A), so that each of the pre-select line contacts 119 (see FIG. 8A) may be separated into two select line contacts 119A and 119B by some trenches TC. Thus, the two pre-select line contacts 119 (see FIG. 8A) contacting the conductive layer 115 for the drain select line disposed on the same layer may be separated into four select line contacts 119A and 119B corresponding to the first cell area, the second cell area, the third cell area, and the fourth cell area, respectively. The horizontal cross-section of each of the select line contacts 119A and 119B may be semicircular or rectangular. In some embodiments, the conductive layer 115 located at the uppermost position is directly coupled to a select line contact (i.e., 119A or 119B) or pre-select line contact 119 without any intervening conductive layer or layers between the conductive layer 115 located at the uppermost position and the select line contact or pre-select line contact. The conductive layer 115 located at the uppermost position may be allocated as a drain select line for some embodiments. For example, as shown in FIG. 9B the conductive layer 115 located at the uppermost position is the conductive layer 115 directly coupled to the select line contact 119A and the select line contact 119B and for reference is the conductive layer 115 positioned furthest away from the source line layer 101 in this example. For example, as shown in FIG. 9B the conductive layer 115 located at the uppermost position is the conductive layer 115 directly coupled to the select line contact 119A and the select line contact 119B and for reference is the conductive layer 115 positioned second furthest away from the source line layer 101 in this example.

As described above, according to an embodiment of the present disclosure, one pre-select line contact is formed for two cell areas to form the select line contacts corresponding to the plurality of cell areas. In the trench forming process for separating the drain select line, the pre-select line contact is separated into two by the trench, and a process is performed so that select line contacts corresponding to each cell area are formed. Thus, in an embodiment, the process of forming the select line contacts can be more easily performed, and process defects in which the select line contacts corresponding to adjacent cell areas contact each other can be reduced.

Subsequently, the interior of each trench TC is filled with the insulating layer to form a separation pattern 123. The separation pattern 123 may be formed of an oxide layer.

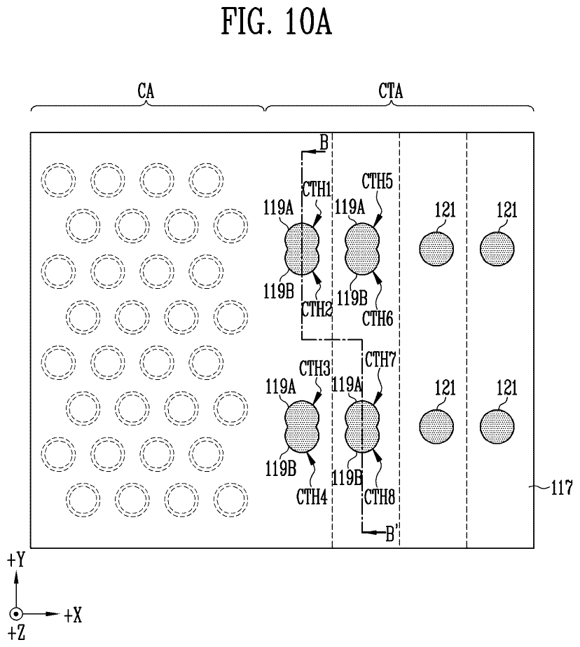

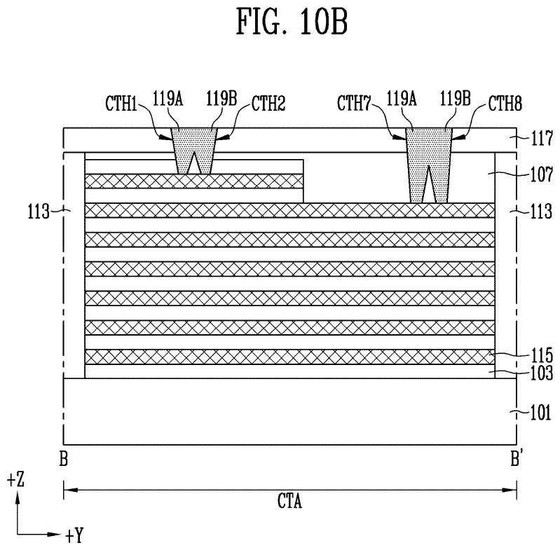

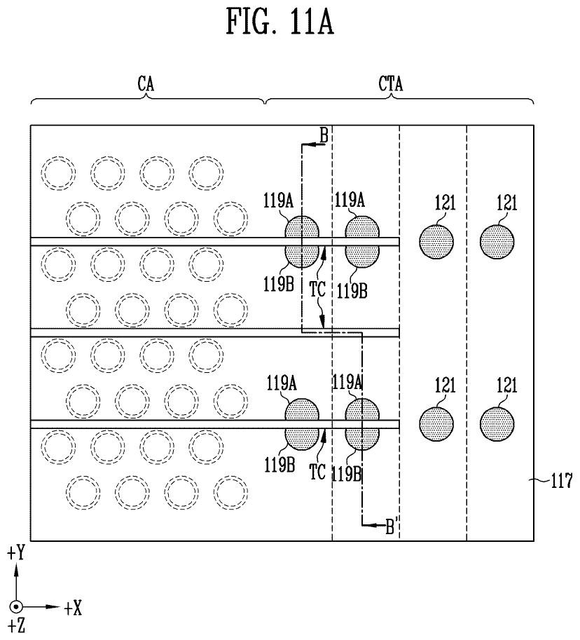

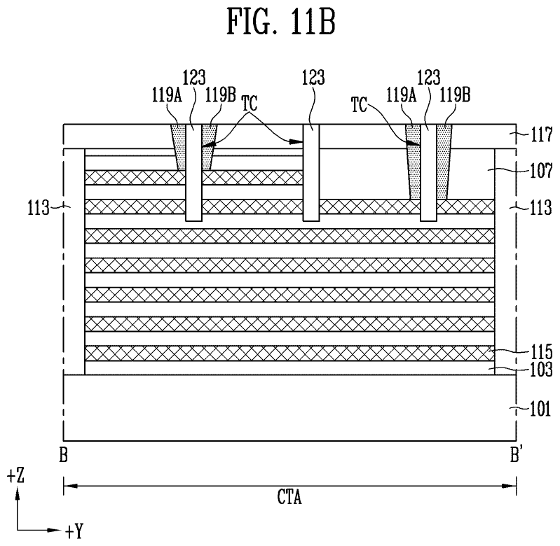

FIGS. 10A, 10B, 11A, and 11B are views for explaining a method of manufacturing a memory device according to an embodiment of the present disclosure.

The method of manufacturing the memory device according to an embodiment of the present disclosure may perform the same process steps as those described with reference to FIGS. 4A, 4B, 5A, 5B, 5C, 6, 7A, 7B, and 7C, and then perform the process steps corresponding to those of FIGS. 10A, 10B, 11A, and 11B.

Referring to FIGS. 10A and 10B, a second upper insulating layer 117 is formed over the entire structure of the cell array area CA and the contact area CTA. The second upper insulating layer 117 may be formed of an oxide layer.

Subsequently, a portion of the pad of the conductive layers 115 may be exposed through an etching process that etches the second upper insulating layer 117 and the first upper insulating layer 107 formed on the contact area CTA. As the etching process, an anisotropic dry etching process may be performed.

For instance, when the cell array area CA is divided into four cell areas CA1, CA2, CA3, and CA4 as illustrated in FIG. 3A, four contact holes CTH1, CTH2, CTH3, and CTH4 corresponding to the four cell areas CA1, CA2, CA3, and CA4, respectively may be formed, and the four contact holes CTH1, CTH2, CTH3, and CTH4 may expose the pad of the conductive layer 115 disposed on the uppermost portion and used as the drain select line among the conductive layers 115. Further, four contact holes CTH5, CTH6, CTH7, and CTH8 corresponding to the four cell areas CA1, CA2, CA3, and CA4, respectively may be formed, and the four contact holes CTH5, CTH6, CTH7, and CTH8 may expose the pad of the conductive layer 115 disposed under the conductive layer 115 disposed on the uppermost portion to be adjacent thereto and used as the drain select line among the conductive layers 115.

In the process of forming the above-described contact holes CTH1, CTH2, CTH3, CTH4, CTH5, CTH6, CTH7, and CTH8, adjacent contact holes CTH1 and CTH2 or CTH3 and CTH4 or CTH5 and CTH6 or CTH7 and CTH8 may be formed so that the distance between the contact holes becomes shorter during the etching process, and thereby the contact holes contact each other as illustrated in the drawings.

Subsequently, the interiors of the contact holes CTH1, CTH2, CTH3, CTH4, CTH5, CTH6, CTH7, and CTH8 may be filled with a conductive material to form the select line contacts 119A and 119B. At this time, when the distance between the contact holes is so close that the contact holes contact each other, the adjacent select line contacts 119A and 119B may be physically coupled to each other.

During the process of forming the above-described contact holes CTH1, CTH2, CTH3, CTH4, CTH5, CTH6, CTH7, and CTH8 and the select line contacts 119A and 119B, the process of forming the contact hole through which the pad of the remaining conductive layers 115 is exposed and the process of forming the word line contact 121 in the contact hole may be performed together.

Referring to FIGS. 11A and 11B, the etching process is performed to form trenches TC penetrating the second upper insulating layer 117, the first upper insulating layer 107, at least two first material layers 103 disposed on an upper portion among the plurality of first material layers 103, and at least one conductive layer 115 disposed on an upper portion among the plurality of conductive layers 115. As the etching process for forming the trenches TC, an anisotropic dry etching process may be performed.

The trenches TC may correspond to the first to third separation patterns SP1 to SP3 illustrated in FIGS. 3A, 3B, and 3C, respectively. For instance, any one of the trenches TC may extend along the X-axis between the first cell area CA1 (see FIG. 3A) and the second cell area CA2 (see FIG. 3A). Further, any one of the trenches TC may extend along the X-axis between the second cell area CA2 (see FIG. 3A) and the third cell area CA3 (see FIG. 3A). Furthermore, any one of the trenches TC may extend along the X-axis between the third cell area CA3 (see FIG. 3A) and the fourth cell area CA4 (see FIG. 3A). The trenches TC may be formed to penetrate the upper conductive layers 115 used as the drain select line, among the plurality of conductive layers 115. Thus, the conductive layers 115 disposed on the upper portion and used as the drain select lines corresponding to the first cell area CA1 (see FIG. 3A), the second cell area CA2 (see FIG. 3A), the third cell area CA3 (see FIG. 3A), and the fourth cell area CA4 (see FIG. 3A) are separated from each other by the trenches TC.

In an embodiment, although it is shown that the trenches TC are formed between the cell plugs CP, some trenches TC may be formed to overlap some of the cell plugs CP. In this case, the cell plugs CP overlapping some trenches TC may be referred to as dummy cell plugs.

The trenches TC may extend to the contact area CTA, and some trenches TC may penetrate between adjacent select line contacts 119A and 119B, so that the adjacent select line contacts 119A and 119B may be physically separated from each other by the trenches TC. Thus, the four select line contacts 119A and 119B contacting the conductive layer 115 for the drain select line disposed on the same layer may correspond to the first cell area, the second cell area, the third cell area, and the fourth cell area, respectively, and may be physically and electrically separated from each other.

Subsequently, the interior of each trench TC is filled with the insulating layer to form a separation pattern 123. The separation pattern 123 may be formed of an oxide layer.

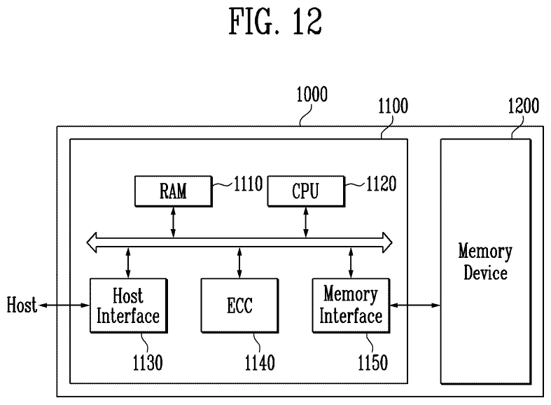

FIG. 12 is a block diagram illustrating the configuration of a memory system according to an embodiment of the present disclosure.

Referring to FIG. 12, a memory system 1000 according to the embodiment of the present disclosure includes a memory device 1200 and a controller 1100.

The memory device 1200 may be used to store data information having a variety of data formats such as text, graphics, and software codes. The memory device 1200 may be the memory devices, described with reference to FIGS. 1, 2, 3A, 3B, and 3C, and may be manufactured according to the manufacturing methods, described with reference to FIGS. 4A, 4B, 5A, 5B, 5C, 6, 7A, 7B, 7C, 8A, 8B, 8C, 9A, and 9B or 10A, 10B, 11A, and 11B. The structure of the memory devices 1200 and the manufacturing methods thereof are the same as those described above, and thus detailed description thereof will be omitted.

The controller 1100 may be connected to a host and the memory device 1200, and may access the memory device 1200 in response to a request from the host. For example, the controller 1100 may control read, write, erase, and background operations of the memory device 1200.

The controller 1100 includes random access memory (RAM) 1110, central processing unit (CPU) 1120, a host interface 1130, an error correction code (ECC) circuit 1140, a memory interface 1150, etc.

Here, the RAM 1110 may be used as a working memory of the CPU 1120, a cache memory between the memory device 1200 and the host, a buffer memory between the memory device 1200 and the host, or the like. For reference, the RAM 1110 may be replaced with a static random access memory (SRAM), a read only memory (ROM), or the like.

The CPU 1120 may control the overall operation of the controller 1100. For example, the CPU 1120 may operate firmware such as a flash translation layer (FTL) stored in the RAM 1110.

The host interface 1130 may perform interfacing with the host. In an embodiment, the controller 1100 may communicate with the host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial-ATA protocol, a parallel-ATA protocol, a small computer system interface (SCSI) protocol, an enhanced small disk interface (ESDI) protocol, an integrated drive electronics (IDE) protocol, and a private protocol.

The ECC circuit 1140 may use an error correction code (ECC) to detect and correct errors in data read from the memory device 1200.

The memory interface 1150 may perform interfacing with the memory device 1200. For example, the memory interface 1150 includes a NAND interface or a NOR interface.

For reference, the controller 1100 may further include a buffer memory (not illustrated) for temporarily storing data. Here, the buffer memory may be used to store data that is transferred to an external device through the host interface 1130 or data that is transferred from the memory device 1200 through the memory interface 1150. The controller 1100 may further include a ROM which stores code data to interface with the host.

Because the memory system 1000 according to an embodiment of the present disclosure includes the memory device 1200 having improved integration and enhanced characteristics, the integration and characteristics of the memory system 1000 may also be improved.

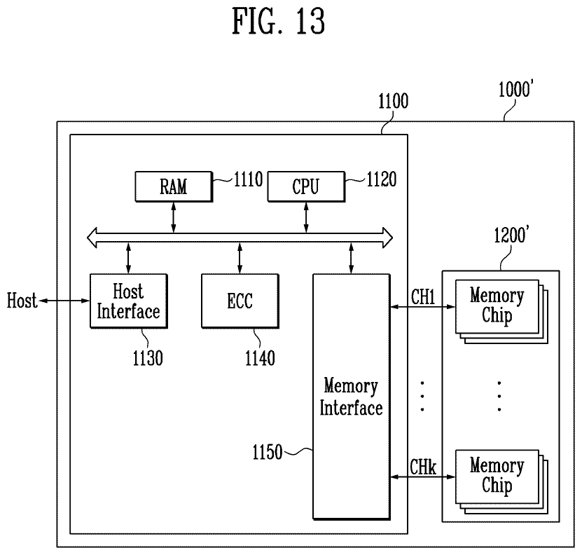

FIG. 13 is a block diagram illustrating the configuration of a memory system according to an embodiment of the present disclosure. Hereinafter, repetitive description of configurations identical to those described above will be omitted.

Referring to FIG. 13, a memory system 1000′ according to an embodiment of the present disclosure may include a memory device 1200′ and a controller 1100. Also, the controller 1100 may include a RAM 1110, a CPU 1120, a host interface 1130, an ECC circuit 1140, a memory interface 1150, etc.

The memory device 1200′ may be a volatile memory, and the memory device 1200′ may be the memory devices, described with reference to FIGS. 1, 2, 3A, 3B, and 3C, and may be manufactured according to the manufacturing methods, described with reference to FIGS. 4A, 4B, 5A, 5B, 5C, 6, 7A, 7B, 7C, 8A, 8B, 8C, 9A, and 9B or 10A, 10B, 11A, and 11B. The structure of the memory devices 1200′ and the manufacturing methods thereof are the same as those described above, and thus detailed description thereof will be omitted.

Further, the memory device 1200′ may be a multi-chip package including a plurality of memory chips. The plurality of memory chips may be divided into a plurality of groups. The plurality of groups may communicate with the controller 1100 through first to k-th channels CH1 to CHk. Also, the memory chips of each group may communicate with the controller 1100 through a common channel. For reference, the memory system 1000′ may be modified such that each single memory chip is connected to a corresponding single channel.

As described above, because the memory system 1000′ according to an embodiment of the present disclosure includes the memory device 1200′ having improved integration and enhanced characteristics, the integration and characteristics of the memory system 1000′ may also be improved. In particular, in an embodiment, the memory device 1200′ may be formed of a multi-chip package, whereby the data storage capacity of the memory system 1000′ may be increased, and the operating speed thereof can be enhanced.

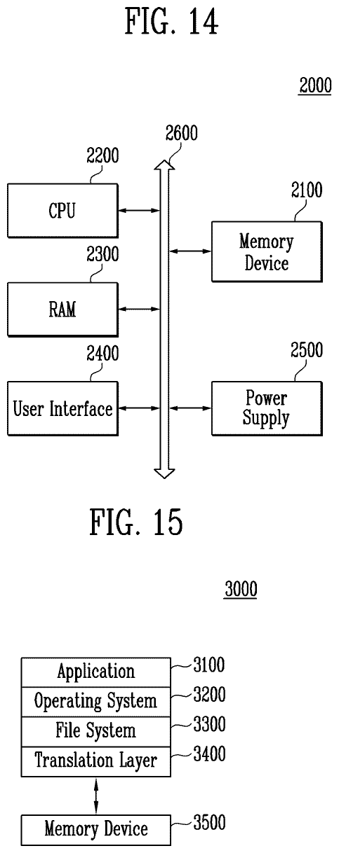

FIG. 14 is a block diagram illustrating the configuration of a computing system according to an embodiment of the present disclosure. Hereinafter, repetitive description of configurations identical to those described above will be omitted.

Referring to FIG. 14, a computing system 2000 according to an embodiment of the present disclosure may include a memory device 2100, a CPU 2200, a RAM 2300, a user interface 2400, a power supply 2500, a system bus 2600, etc.

The memory device 2100 stores data provided through the user interface 2400, data processed by the CPU 2200, etc. Further, the memory device 2100 may be electrically connected to the CPU 2200, the RAM 2300, the user interface 2400, the power supply 2500, etc. through the system bus 2600. For example, the memory device 2100 may be connected to the system bus 2600 through a controller (not illustrated) or, alternatively, directly connected to the system bus 2600. In the case where the memory device 2100 is directly connected to the system bus 2600, the function of the controller may be performed by the CPU 2200, the RAM 2300, etc.

Here, the memory device 2100 may be a volatile memory, and the memory device 2100 may be the memory devices, described with reference to FIGS. 1, 2, 3A, 3B, and 3C, and may be manufactured according to the manufacturing methods, described with reference to FIGS. 4A, 4B, 5A, 5B, 5C, 6, 7A, 7B, 7C, 8A, 8B, 8C, 9A, and 9B, or 10A, 10B, 11A, and 11B. The structure of the memory device 2100 and the manufacturing method thereof are the same as those described above, and thus detailed description thereof will be omitted.

Further, as described above with reference to FIG. 13, the memory device 2100 may be a multi-chip package including a plurality of memory chips.

The computing system 2000 having the above-described configuration may be a computer, a ultra-mobile PC (UMPC), a workstation, a net-book, a personal digital assistants (PDA), a portable computer, a web tablet, a wireless phone, a mobile phone, a smartphone, an e-book, a portable multimedia player (PMP), a game console, a navigation device, a black box, a digital camera, a 3-dimensional (3D) television, a digital audio recorder, a digital audio player, a digital picture recorder, a digital picture player, a digital video recorder, a digital video player, a device capable of transmitting/receiving information in an wireless environment, one of various devices constituting a home network, one of various electronic devices constituting a computer network, one of various electronic devices constituting a telematics network, an RFID device, or the like.

As described above, because the computing system 2000 according to an embodiment of the present disclosure includes the memory device 2100 having improved integration and enhanced characteristics, the characteristics of the computing system 2000 may also be improved.

FIG. 15 is a block diagram illustrating a computing system according to an embodiment of the present disclosure.

Referring to FIG. 15, a computing system 3000 according to an embodiment of the present disclosure may include a software layer which includes an operating system 3200, an application 3100, a file system 3300, a translation layer 3400, etc. Further, the computing system 3000 may include a hardware layer such as a memory device 3500.

The operating system 3200 may manage software resources, hardware resources, etc. of the computing system 3000, and may control program execution by the CPU. The application 3100 may be any of various applications to be executed in the computing system 3000, and may be a utility executed by the operating system 3200.

The file system 3300 may refer to a logical structure for controlling data, files, etc. which are present in the computing system 3000, and may organize files or data to be stored in the memory device 3500 or the like based on certain rules. The file system 3300 may be determined depending on the operating system 3200 used in the computing system 3000. For example, when the operating system 3200 is Microsoft's Windows series, the file system 3300 may be a file allocation table (FAT), an NT file system (NTFS), or the like. Also, when the operating system 3200 is the Unix/Linux family, the file system 3300 may be an extended file system (EXT), a Unix file system (UFS), a journaling file system (JFS), or the like.

Although the operating system 3200, the application 3100 and the file system 3300 are illustrated as separate blocks in the drawing, the application 3100 and the file system 3300 may be included in the operating system 3200.

The translation layer 3400 translates an address into a form suitable for the memory device 3500 in response to a request from the file system 3300. For example, the translation layer 3400 may translate a logical address generated by the file system 3300 into a physical address of the memory device 3500. Here, mapping information of the logical address and physical address may be stored in the form of an address translation table. For example, the translation layer 3400 may be a flash translation layer (FTL), a universal flash storage link layer (ULL), or the like.

The memory device 3500 may be a volatile memory, and the memory device 3500 may be the memory device, described with reference to FIGS. 1, 2, 3A, 3B, and 3C, and may be manufactured according to the manufacturing method, described with reference to FIGS. 4A, 4B, 5A, 5B, 5C, 6, 7A, 7B, 7C, 8A, 8B, 8C, 9A, and 9B or 10A, 10B, 11A, and 11B. The structure of the memory device 3500 and the manufacturing method thereof are the same as those described above, and thus detailed description thereof will be omitted.

The computing system 3000 having the above-mentioned configuration may be divided into an operating system layer implemented in a higher-level area and a controller layer implemented in a lower-level area. The application 3100, the operating system 3200, and the file system 3300 may be included in the operating system layer, and may be driven by a working memory of the computing system 3000. Also, the translation layer 3400 may be included in the operating system layer or the controller layer.

As described above, because the computing system 3000 according to an embodiment of the present disclosure includes the memory device 3500 having improved integration and enhanced characteristics, the characteristics of the computing system 3000 may also be improved.

According to an embodiment of the present disclosure, the difficulty of a process can be reduced and defects in the process can be reduced by securing a margin for forming a contact plug coupled to a select line on a contact area.

What is claimed is:

1. A memory device, comprising:
a stacked structure including a plurality of conductive layers and a plurality of interlayer insulating layers that are alternately stacked in a cell array area and a contact area;
a plurality of cell plugs formed within the stacked structure in the cell array area;
a plurality of select line contacts coupled to the conductive layer that is allocated as a select line among the plurality of conductive layers; and
a separation pattern penetrating the conductive layer that is allocated as the select line in the cell array area, the separation pattern extending from the cell array area to the contact area,
wherein the separation pattern separates the plurality of select line contacts from each other.

2. The memory device according to claim 1, wherein the separation pattern penetrates the conductive layer for the select line in the contact area, and is positioned between the plurality of select line contacts.

3. The memory device according to claim 1, wherein a horizontal cross-section of each of the plurality of select line contacts is substantially semicircular or substantially rectangular.

4. The memory device according to claim 1,
wherein conductive layers other than the conductive layer allocated as the select line among the plurality of conductive layers in the contact area are conductive layers allocated as word lines, and
wherein the memory device further comprises:
word line contacts coupled to the conductive layers allocated as the word line, respectively.

5. The memory device according to claim 1, wherein the separation pattern is disposed between the cell plugs, and overlaps a portion of the cell plugs.

6. The memory device according to claim 1, further comprising:
an upper insulating layer formed on an upper portion of the stacked structure,
wherein the separation pattern penetrates the upper insulating layer.

7. The memory device according to claim 1,
wherein the cell array area comprises a first cell area and a second cell area, and
wherein the separation pattern is disposed on a boundary between the first cell area and the second cell area to physically separate the conductive layer allocated as the select line in the first cell area from the conductive layer allocated as the select line in the second cell area.

8. The memory device according to claim 7, wherein each of the plurality of select line contacts is coupled to the conductive layer allocated as the select line in the first cell area or the conductive layer allocated as the select line in the second cell area.

9. A memory device, comprising:
a stacked structure including a plurality of conductive layers and a plurality of interlayer insulating layers that are alternately stacked in a cell array area and a contact area, the cell array area including first, second, third, and fourth cell areas;
a plurality of cell plugs formed within the stacked structure in the cell array area;
a plurality of select line contacts coupled to the conductive layer that is allocated as a select line among the plurality of conductive layers;
a first separation pattern disposed between the first cell area and the second cell area, and penetrating the conductive layer that is allocated as the select line in the cell array area, the first separation pattern extending from the cell array area to the contact area;
a second separation pattern disposed between the second cell area and the third cell area, and penetrating the conductive layer that is allocated as the select line in the cell array area, the second separation pattern extending from the cell array area to the contact area; and
a third separation pattern disposed between the third cell area and the fourth cell area, and penetrating the conductive layer that is allocated as the select line in the cell array area, the third separation pattern extending from the cell array area to the contact area,
wherein the first separation pattern and the third separation pattern separate the plurality of select line contacts from each other.

10. The memory device according to claim 9,
wherein each of the first, second, and third separation patterns penetrates the conductive layer that is allocated as the select line in the contact area, and
wherein the first separation pattern and the third separation pattern directly contact each of the plurality of select line contacts, and are positioned between the plurality of select line contacts.

11. The memory device according to claim 9, wherein a horizontal cross-section of each of the plurality of select line contacts is substantially semicircular or substantially rectangular.

12. The memory device according to claim 9,
wherein conductive layers other than the conductive layer allocated as the select line among the plurality of conductive layers in the contact area are conductive layers allocated as word lines, and
the memory device further comprises:
word line contacts coupled to the conductive layers allocated as the word line, respectively.

13. The memory device according to claim 9, wherein each of the first, second, and third separation patterns is disposed between the cell plugs, and overlaps a portion of the cell plugs.

14. The memory device according to claim 9, further comprising:
an upper insulating layer formed on an upper portion of the stacked structure,
wherein each of the first, second, and third separation patterns penetrates the upper insulating layer.

15. A method of manufacturing a memory device, comprising:
forming a stacked structure by alternately stacking a plurality of conductive layers and a plurality of interlayer insulating layers in a cell array area and a contact area;
forming a plurality of cell plugs in the stacked structure in the cell array area;
forming a pre-select line contact coupled to the conductive layer that is allocated as a select line among the plurality of conductive layers;
forming a trench that penetrates the conductive layer that is allocated as the select line, the trench extending from the cell array area to the contact area; and
filling the trench with an insulating layer to form a separation pattern,
wherein the trench penetrates the pre-select line contact to separate the pre-select line contact into a plurality of select line contacts.

16. The method according to claim 15, further comprising:
forming an upper insulating layer on an upper portion of the stacked structure, before forming the pre-select line contact,
wherein the pre-select line contact penetrates the upper insulating layer to be coupled to the conductive layer that is allocated as the select line.

17. The method according to claim 16, wherein the trench penetrates the upper insulating layer, the pre-select line contact, and the conductive layer that is allocated as the select line in substantially a line shape.

18. The method according to claim 15, wherein the pre-select line contact is formed so that a horizontal cross-section thereof has substantially an elliptical, circular, or rectangular shape.

19. The method according to claim 18, wherein each of the plurality of select line contacts is formed so that a horizontal cross-section thereof has substantially a semicircular or rectangular shape.

20. The method according to claim 15, wherein forming the pre-select line contact comprises forming a word line contact coupled to each of conductive layers allocated as word lines other than the conductive layer that is allocated as the select line among the plurality of conductive layers.

21. A method of manufacturing a memory device, comprising:
forming a stacked structure by alternately stacking a plurality of conductive layers and a plurality of interlayer insulating layers in a cell array area and a contact area, the cell array area including a first cell area and a second cell area;
forming a plurality of cell plugs within the stacked structure in the cell array area;
forming a first select line contact and a second select line contact coupled to the conductive layer that is allocated as a select line among the plurality of conductive layers;
forming a trench that penetrates the conductive layer that is allocated as the select line between the first cell area and the second cell area, the trench extending from the cell array area to the contact area; and
filling the trench with an insulating layer to form a separation pattern,
wherein the trench separates the first select line contact and the second select line contact from each other.
